(19) United States
(12) Patent Application Publication
(10) Pub. No.: US 2013/0224100 A1
(43) Pub. Date: Aug. 29, 2013

(54) ELECTROMAGNETIC MIXING FOR NITRIDE CRYSTAL GROWTH

(71) Applicant: THE REGENTS OF THE UNIVERSITY OF CALIFORNIA, (US)

(72) Inventor: Paul Von Dollen, Santa Barbara, CA (US)

(73) Assignee: THE REGENTS OF THE UNIVERSITY OF CALIFORNIA, Oakland, CA (US)

(21) Appl. No.: 13/776,353

(22) Filed: Feb. 25, 2013

Related U.S. Application Data
(60) Provisional application No. 61/603,143, filed on Feb. 24, 2012.

(51) Int. Cl. F27B 14/06; C30B 29/40; C30B 15/30

(52) U.S. Cl. CPC F27B 14/061; C30B 15/305; C30B 29/403
USPC 423/409; 117/30; 117/217

(57) ABSTRACT

A method and apparatus for bulk Group-III nitride crystal growth through inductive stirring in a sodium flux growth technique. A helical electromagnetic coil is closely wound around a non-conducting cylindrical crucible containing a conductive crystal growth solution, including both precursor gallium and sodium, wherein a nitrogen-containing atmosphere can be maintained at any pressure. A seed crystal is introduced with the crystal's growth interface submerged slightly below the solution's surface. Electrical contact is made to the coil and an AC electrical field is applied at a specified frequency, in order to create eddy currents within the conductive crystal growth solution, resulting in a steady-state flux of solution impinging on the submerged crystal's growth interface.

### CROSS REFERENCE TO RELATED APPLICATION

This application claims the benefit under 35 U.S.C. Section 119(e) of U.S. Provisional Patent Application Ser. No. 61/603,143, filed on Feb. 24, 2012, by Paul Von Dollen, and entitled “ELECTROMAGNETIC MIXING FOR NITRIDE CRYSTAL GROWTH,” attorneys' docket number 30794.447-US-P1 (2012-506-1), which application is incorporated by reference herein.

This application is related to the following co-pending and commonly-assigned application:

U.S. Utility application Ser. No. 13/744,854, filed on Jan. 18, 2013, by Paul Von Dollen, James S. Speck, and Siddha Pimputkar, entitled “CRYSTAL GROWTH USING NON-THERMAL ATMOSPHERIC PRESSURE PLASMAS,” attorney's docket number 30794.444-US-U1 (2012-456-2), which application claims the benefit under 35 U.S.C. Section 119(e) of U.S. Provisional Application Ser. No. 61/588,028, filed on Jan. 18, 2012, by Paul Von Dollen, James S. Speck, and Siddha Pimputkar, entitled “CRYSTAL GROWTH USING NON-THERMAL ATMOSPHERIC PRESSURE PLASMAS,” attorney's docket number 30794.444-US-P1 (2012-456-1);

both of which applications are incorporated by reference herein.

### BACKGROUND OF THE INVENTION

1. Field of the Invention

This invention relates to a method for electromagnetic mixing for Group III nitride crystal growth.

2. Description of the Related Art

There is a need and a desire for optoelectronic devices (LEDs, lasers, high frequency/high power switches) of increased performance at reduced cost. Group III nitrides (AlN, InN, GaN) are well suited for these applications, but current device performance/cost ratios do not facilitate widespread market penetration. In particular, the performance/cost ratio for GaN is significantly hampered by heteroepitaxial fabrication techniques on non-native substrates (Al₂O₃, Si, SiC, etc.). Homoepitaxy on native GaN substrates represents a significant opportunity for improved device performance at reduced cost.

Native GaN substrates can be derived through wafering or slicing bulk GaN boules, as is the case with silicon, GaAs, GaP, etc. However, bulk GaN crystal growth at industrially relevant scale (both cross-sectional area as well as realized growth rates) has mostly eluded research and development efforts. 2″-class bulk GaN wafers are beginning to reach commercialization, but they are currently too costly for large-volume applications such as LEDs. Furthermore, it is unclear if state-of-the-art commercialized growth techniques, such as ammonothermal, hydride vapor phase epitaxy (HVPE), etc., can be feasibly and economically scaled to next generation 4″ and 6″ (and beyond) wafer platforms. Clear motivation and market opportunity exists for development of bulk GaN crystal growth at decreased cost and larger cross-sectional areas.

Bulk GaN crystals are currently grown at the research scale using a “sodium flux” (or “Na Flux”) method of GaN crystal growth, where a melt of Ga and Na is exposed to a nitrogen atmosphere to form solid GaN. GaN will crystallize from a pure Ga melt exposed to a nitrogen-containing atmosphere, but the growth rate is negligible unless high temperatures and pressures are used. Theoretically, the Na promotes dissociation of the N₂ gas molecule, and the Na/Ga solution exhibits a relatively large equilibrium dissolved atomic Nitrogen concentration. The driving force for solid GaN growth is provided by introducing a temperature gradient within the solution, and growth rates as high as ˜30 μm/hr are realized using the Na Flux method. Even when using Na, pressures greater than 30 atm and temperatures ˜800° C. are necessary to realize appreciable crystal growth rates.

One method of growing bulk GaN using a Na-flux technique is described in the cross-referenced applications set forth above, namely U.S. Utility Application Ser. No. 13/744,854, filed on Jan. 18, 2013, by Paul Von Dollen, James S. Speck, and Siddha Pimputkar, entitled “CRYSTAL GROWTH USING NON-THERMAL ATMOSPHERIC PRESSURE PLASMAS,” attorney's docket number 30794.444-US-U1 (2012-456-2), which application claims the benefit under 35 U.S.C. Section 119(e) of U.S. Provisional Application Ser. No. 61/588,028, filed on Jan. 18, 2012, by Paul Von Dollen, James S. Speck, and Siddha Pimputkar, entitled “CRYSTAL GROWTH USING NON-THERMAL ATMOSPHERIC PRESSURE PLASMAS,” attorney's docket number 30794.444-US-P1 (2012-456-1), both of which applications are incorporated by reference herein.

Growth of bulk GaN using the Na-flux technique is enhanced by increasing the saturation of N species in the vicinity of the growth interface. Due to the apparently low diffusivity of N in Na or Na—Ga melts at growth temperatures (˜800° C.), growth rates are low without mixing of the melt to increase homogeneity. Currently, mixing is accomplished using a mechanical “swinging” motion of the entire heated stainless steel furnace. This mixing method is likely to become increasing complicated and expensive with increased crystal diameters.

Fluids can be stirred and mixed in various ways including mechanical stirring using a paddle or agitator, convection mixing, gas bubble mixing, etc. In the case of conductive fluids, strong mixing occurs as a response to Lorentz forces generated by applied time-varying electromagnetic fields, as described in H. K. Moffatt, “Electromagnetic stirring,” Phys. Fluids A, 3 (5), May 1991, pp. 1336-1343 (hereinafter “Moffatt”), which is incorporated by reference herein, wherein FIGS. 9(a) and 9(b) of Moffatt show fluid motion in response to electromagnetic forces. Rapid and complete homogenization can be readily accomplished without directly contacting the conductive fluid. This effect, known as electromagnetic stirring or inductive stirring, is widely exploited in large-scale molten metal processing (steel production, nickel alloy production, etc.).

Although electromagnetic stirring or inductive stirring has been used in other areas, it has not been applied to the growth of Group-III nitride crystals. If the applied electromagnetic fields are arranged cylindrically around a conductive crystal growth solution, solution flow will occur in one or more vertically directed recirculation cells with a resulting net upward velocity. A crystal placed at the solution's surface will experience a constant flow of liquid directed onto the submerged crystal surface. If the fluid contains a constant concentration of solute, the solute flux is given by the concentration multiplied by the velocity. The velocity and therefore flux can be readily controlled through the current and/or frequency of the applied electromagnetic fields.

Thus, there is a need in the art for improved methods of mixing for Group-III nitride crystal growth. The present invention satisfies these needs.

### SUMMARY OF THE INVENTION

To overcome the limitations in the prior art described above, and to overcome other limitations that will become apparent upon reading and understanding the present specification, the present invention discloses a method and apparatus for bulk Group III nitride crystal growth through inductive stirring in a sodium flux growth technique. A helical electromagnetic coil is closely wound around a non-conducting cylindrical crucible containing a conductive crystal's growth solution, including both precursor gallium and sodium, wherein a nitrogen-containing atmosphere can be maintained at any pressure. A seed crystal is introduced with the crystal growth interface submerged slightly below the solution's surface. Electrical contact is made to the coil and an AC electrical field is applied at a specified frequency, in order to create eddy currents within the conductive crystal growth solution, resulting in a steady-state flux of solution impinging on the submerged crystal's growth interface.

### BRIEF DESCRIPTION OF THE DRAWINGS

Referring now to the drawings in which like reference numbers represent corresponding parts throughout:

FIG. 1 is a general schematic of a flux-based crystal growth method.

FIG. 2 is a general schematic of a proposed flux-based crystal growth method showing an electromagnetic coil for heating and mixing according to the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Technical Description

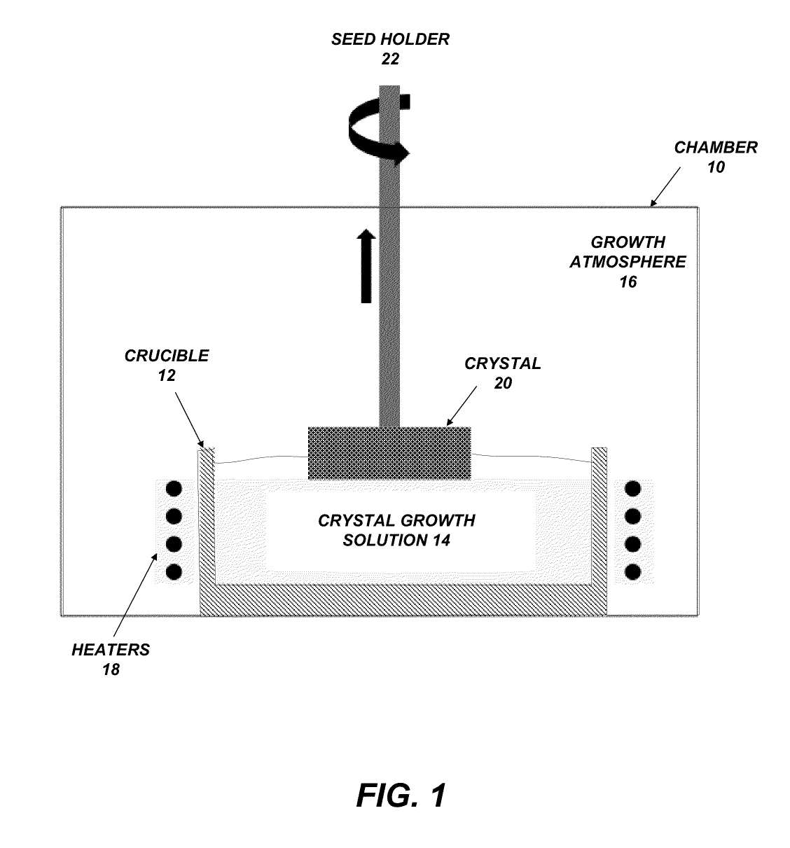

FIG. 1 is a schematic that illustrates a method and apparatus used for growing a compound crystal, such as a Group-III nitride crystal, using a flux-based growth method.

In one embodiment of the present invention, the flux-based crystal growth method makes use of a reactor vessel or chamber 10 (which may be open or closed) having a refractory crucible 12, comprised of a non-reactive material such as boron nitride or alumina, that contains a liquid, fluid or melt that is a crystal growth solution 14.

The solution 14 is comprised of at least one Group-III metal, such as Al, Ga and/or In, and at least one alkali metal, such as Na. In the preferred embodiment, the solution 14 is a mixture of predominantly containing sodium (>50 mol %) with the remainder gallium, as this alloy range is known to have a high nitrogen solubility and facilitates high crystal growth rates>30 μm/hr. The solution 14 may contain any number of additional elements, compounds, or molecules to modify growth characteristics and crystal properties, such as B, Li, K, Rb, Cs, Be, Mg, Ca, Sr, Ba, Sr, C, Bi, Sb, Sn, Be, Si, Ge, Zn, P and/or N.

Additionally, the reactor vessel 10 contains a growth atmosphere 16 in which the solution 14 is placed, that can be a nitrogen-containing atmosphere 16, including, but not limited to, atomic nitrogen N, diatomic N₂, ammonia NH₃, hydrazine N₂H₆, or an atmosphere 16 with only trace amounts of nitrogen present, for example, an atmosphere comprised mainly of hydrogen, argon, etc. The atmosphere 16 may be at vacuum, or may have a pressure greater than approximately 1 atmosphere (atm) and up to approximately 1000 atm.

The crucible 12 may include one or more heaters 18 so that the solution 14 may be heated and then held at one or more set temperatures, and one or more temperature gradients may be established within the reactor vessel 10. Preferably, the crucible 12, solution 14, seed 20 and seed holder 22 are contained within the reactor vessel 10 at a temperature above the solution 14 melting point. In one embodiment, the solution 14 is held at a temperature greater than approximately 200° C. and below approximately 1200° C. during growth.

The chemical potential of the solution 14 may be raised or lowered with respect to vacuum through the use of a power source (not shown) operating at arbitrary frequencies (f>=0 Hz) and voltages. The solution 14 and atmosphere 16 in which it has been placed may be subject to electromagnetic fields, both static and/or dynamic.

A seed crystal 20 upon which the compound crystal is grown is affixed to a seed holder 22, which allows movement, rotation and retraction during the growth process, by mechanical or by other means. For example, the seed 20 can be affixed to the seed holder 22 using ceramic cement or metals such as Ag, Au, Pd, Pt, etc., or blends such as Ag/Pd, Au/Pd, etc., wherein the metals are introduced as suspensions in a viscoelastic carrier and comprise pastes. After affixing the seed crystal 20, the bond must be formed and the binder removed by heating the seed holder 22 and seed 20.

Once the reactor vessel 10 containing the solution 14 has been adequately prepared, one or more surfaces of the seed crystal 20 can be brought into contact with the solution 14, or the solution 14 can be brought into contact with one or more surfaces of the seed 20, wherein the seed 20 is at least partially exposed to the atmosphere 16. Once the seed 20 and the solution 14 are brought into contact, the seed 20 and/or the solution 14 may be subject to mechanical movements of the seed holder 22, such as mixing, stirring or agitating, to shorten the time required to saturate the solution 14 with nitrogen.

In a preferred embodiment, the seed 20 is a Group-III nitride crystal, such as GaN, etc., and may be a single crystal or a polycrystal. However, this should not be seen as limiting for this invention. This invention specifically includes growing a Group-III nitride crystal on an arbitrary material, wherein the seed 20 may be an amorphous solid, a polymer containing material, a metal, a metal alloy, a semiconductor, a ceramic, a non-crystalline solid, a poly-crystalline material, an electronic device, an optoelectronic device.

When the seed 20 is a Group-III nitride crystal, it may have one or more facets exposed, including polar, nonpolar and semipolar planes. For example, the Group-III nitride seed crystal 20 may have a large polar c-plane {0001} facet or a {0001} approaching facet exposed; or the Group-III nitride seed crystal 20 may have a large nonpolar m-plane {10-10} facet or a {10-10} approaching facet exposed; or the Group-III nitride seed crystal 20 may have a large semipolar {10-11} facet or a {10-11} approaching facet exposed; or the Group-III nitride seed crystal 20 may have a large nonpolar a-plane {11-20} facet or a {11-20} approaching facet exposed.

The flux method that is used to coat the seed 20 and form a resulting Group-III nitride crystal on the seed 20 is based on evaporation from the solution 14, but may also include a solid source containing Group-III and/or alkali metals, which results in the formation of a layer of Group-III and alkali metal on the surfaces of the seed 20. In one example, the flux method used to coat the seed 20 and form the Group-III nitride crystal on the seed 20 is based on bringing the seed 20 into contact with the solution 14, intermittently or otherwise, by means of dripping and/or flowing the solution 14 over one or more surfaces of the seed 20. In another example, the flux method used to coat the seed 20 and form the Group-III nitride crystal on the seed 20 involves submersing or submerging the seed 20 within the solution 14 and placing one facet of the seed 20 within some specified distance, such as 5 mm, of the interface between the solution 14 and the atmosphere 16. Further, the seed 20 may be rotated and/or moved on a continuous or intermittent basis using the seed holder 22.

The resulting Group-III nitride crystal that is grown on the seed 20 is characterized as AlₓB_{y}Ga_{z}In_{(1-x-y-z)}N, where 0<=x<=1, 0<=y<=1, 0<=z<=1, and x+y+z<=1. For example, the Group-III nitride crystal may be AN, GaN, InN, AlGaN, AlInN, InGaN, etc. In another example, the Group-III nitride crystal may be at least 2 inches in length when measuring along at least one direction. The Group-III nitride crystal may also have layers with different compositions, and the Group-III nitride crystal may have layers with different structural, electronic, optical, and/or magnetic properties.

Thus, FIG. 1 shows a general schematic for flux-based crystal growth where a seed crystal 20 is introduced to the free solution 14 surface and can be rotated as well as raised or lowered by the seed holder 22. GaN will crystallize from a pure Ga melt 14 exposed to a nitrogen-containing atmosphere 16, but the growth rate is negligible unless high temperatures and pressures are used. Theoretically, the Na promotes dissociation of the N₂ gas molecule, and the Na/Ga solution 14 exhibits a relatively large equilibrium dissolved atomic nitrogen concentration. The driving force for solid GaN growth is typically provided by introducing a temperature gradient within the solution 14, and growth rates as high as ˜30 μm/hr may be realized using the flux-based growth method. However, even when using Na, pressures greater than 30 atmospheres (atm) and temperatures ˜800° C. may be necessary to realize appreciable crystal 20 growth rates.

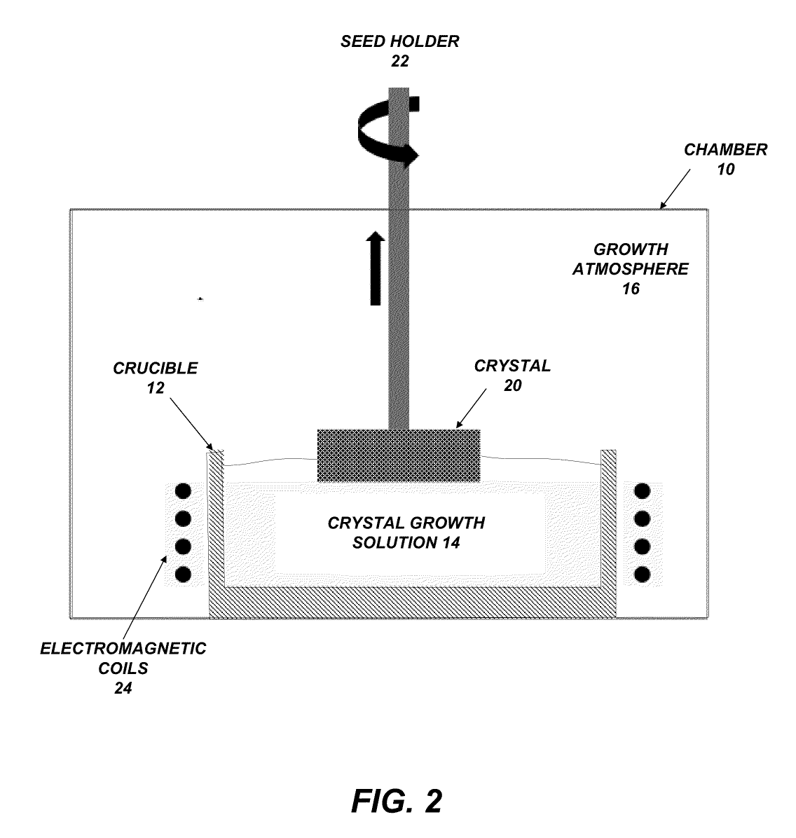

FIG. 2 is a general schematic of an apparatus used in a proposed flux-based crystal growth method for growing a compound crystal that improves solution-based crystal growth through inductive stirring. FIG. 2 is similar to FIG. 1 in that it shows a reactor vessel or chamber 10 for growing a Group-III nitride crystal using a flux-based growth, including a crucible 12 containing a conductive crystal growth solution 14 comprised of at least one Group-III metal, a growth atmosphere 16 containing nitrogen, a seed crystal 20, and a seed holder 22. FIG. 2 is different from FIG. 1 in that it also includes a helical electromagnetic coil 24 in place of the heaters 18 (although alternative embodiments may include both the heaters 18 and the helical electromagnetic coil 24), wherein the solution 14 is inductively stirred or mixed using one or more electromagnetic fields generated by the helical electromagnetic coil 24.

The electromagnetic fields are controlled to create a directed flow of the solution 14 towards the crystal's 20 growth interface. Specifically, the electromagnetic fields are controlled to vary a flow velocity and direction for the solution 14 during the crystal's 20 growth.

To accomplish this, the solution 14 may be electrically conductive. For example, the solution 14 may include at least one of the following conductive metals: Ga, Na, Li, K, Sn, Bi or Ca. In addition, or alternatively, one or more electrically conductive components may exist as a discrete phase within the solution 14, wherein the electrically conductive components include at least one of the following elements: W, Re, Ta, Os, Ir, Pt, Au, Pd, Ni, Cu, Ti, Ru, Fe, C or Si.

In the case of GaN crystal 20 growth using a sodium-gallium solution 14, the stirring by the helical electromagnetic coil 24 allows a much higher nitrogen-species flux to contact the crystal's 20 growth interface, increasing the growth rate. Inductive stirring is non-contact, resulting in higher purity than with mechanical stirrers. Inductive stirring is also readily applicable to large crystal 20 diameters with only a modest increase in cost and complexity.

Inductive stirring can be readily instituted with only minor modification to the existing Na-Flux GaN crystal growth technique. Precursor gallium is added to sodium in the crucible 12, which is placed in contact with the nitrogen-containing atmosphere 16. In the case of inductive stirring, the crucible 12 must be non-conducting to allow direct coupling to the conductive growth solution 14. The nitrogen-containing atmosphere 16 can be maintained at any pressure, as the electromagnetic coupling is not strongly pressure-dependent. The seed crystal 20 (which may be GaN or another material) is introduced at the top or bottom of the molten metal solution 14, or no seed crystal 20 can be used. The solution 14 and crucible 12 are heated to promote dissolution of nitrogen as well as enhance the kinetics for GaN solid deposition. Heating can be accomplished externally or internally (within the nitrogen-atmosphere containing vessel 10). Internal heating can be accomplished by various means, including directly heating the molten metal mixture 14 through inductive coupling of the electromagnetic fields induced by the coil 24.

Inductive stirring is accomplished through coupling of electromagnetic fields directly to the solution 14. The preferable configuration is to excite the conductive coil 24 immediately surrounding the crucible 12 containing the molten metal 14. Eddy current cells are established within the molten metal 14, causing complete homogenization (uniform dissolved nitrogen concentration) and a steady-state flux of nitrogen-enriched molten metal 14 to impinge on the crystal's 20 growth interface. Solid GaN deposits out of the enriched solution 14 at the crystal's 20 growth interface, increasing the crystal 20 volume. The nitrogen-depleted solution 14 is recirculated and stirred into the interior of the melt 14, and the overall nitrogen content maintained through additional nitrogen dissolution from the atmosphere 16.

In one embodiment, the helical electromagnetic coil 24 is closely wound around the non-conducting cylindrical crucible 12 containing the conductive crystal growth solution 14. The seed crystal 20 is introduced with the crystal's 20 growth interface submerged slightly below the solution 14 surface. Electrical contact is made to the coil 24 and an AC electrical field is applied at a specified operating frequency. The eddy currents are created within the conductive crystal growth solution 14 to create a steady-state flux of solution 14 impinging on the submerged crystal's 20 growth interface.

Preferably, the operating frequency of the coil 24 would correspond to a frequency-dependent magnetic Reynold's number of ˜20 to maximize the stirring effect, in accordance with Moffat. According to Moffat, the magnetic Reynold's number related to frequency, Re_{ω}, is given by the following equation:

$${Re}_{ω} = 2 {( \frac{L}{δ} )}^{2} = ω {L}^{2} {μ}_{0} σ$$

where L is the characteristic length, δ is the frequency dependent skin depth, ω is the frequency of the applied field, μ₀ is the permeability of free space (for non-magnetic materials) and σ is the electrical conductivity.

For example, using typical values of ˜4 cm for L, a permeability of free space μ₀ of 4π×10⁻⁷ N/A², and 10⁴ S/cm for σ, a frequency ω of ˜1.6 kHz is necessary to yield an Re_{ω of ˜}20 with a skin depth δ of ˜1.26 cm. When L is ˜2 cm, the frequency ω is ∞6.2 kHz and the corresponding skin depth is 0.64 cm.

However, other considerations, such as power supply cost, availability or ease of control, may dictate the use of a different operating frequency. The stirring effect (melt velocity) is linearly dependent on applied current, and therefore readily controllable during the growth process. For instance, it may be advantageous to impose different melt velocities at different stages of growth (nucleation vs. steady-state).

The end result of this method using this apparatus is an improved crystal 20, such as a Group-III nitride crystal 20. The crystal 20 may be doped, such that it is electronically p-type or n-type. The crystal 20 may be a multi-layer structure, and it may be used to create a substrate for subsequent fabrication of an electronic, optoelectronic or thermoelectric device.

### Variations and Modifications

The crystal growth solution 14 can be any conductive liquid compatible with crystal 20 growth (reasonably solubility of growth species, stability under growth conditions, etc.). Alternatively, stirring may be accomplished by coupling to conductive stirring elements within a non-conductive fluid 14. These could be small metal balls or “dumbbells” which will respond to applied electromagnetic fields to mechanically stir the solution 14, but in a non-contact and controllable fashion. In this latter case, heating could be substantially de-coupled from solution 14 mixing.

The conductive coil 24 can be manufactured from a variety of substances in a variety of cross-sectional configurations. The main criteria are conductivity, as this, in part, determines the efficiency of electromagnetic coupling and compatibility with the growth environment (pressure, temperature and chemistry).

For instance, the coil 24 could be fabricated from copper tubing that is water-cooled to maintain a high conductivity, although this configuration has the added complexity of maintaining a water-cooling system. Alternatively, the coil 24 could be fabricated from a high conductivity metal and gas-cooled. Or, the coil 24 could be not actively cooled at all, with a resulting decrease in coupling efficiency.

The coil 24 cross section can be round, square, rectangular, or any shape. The coil 24 may be positioned inside or outside the reactor vessel 10. Also, the coil 24 may be positioned inside or outside the crucible 12.

The possibility of internal heating directly from the induction coil 24 is another advantage of this invention, as previous efforts included separate systems for heating and stirring. This will result in decreased cost and reduced overall complexity.

Heating from the induction coil 24 itself can be accomplished by direct electromagnetic coupling or, if the coupling efficiency is low, by additional heat conduction from the coil 24 to the solution 14 through the crucible 12.

Molten metal heating can be carried out resistively, inductively, or both simultaneously. For example, a small AC excitation can be superimposed upon a larger DC signal transmitted through the coil 24. The DC signal will act to resistively heat the coil 24 and therefore heat the melt 14 through conduction, while the AC signal will electromagnetically couple with the melt 14, causing further heating.

### Advantages and Benefits

The invention described here has numerous advantages with respect to the state-of-the art for growth of especially GaN crystals.

For example, as compared to “swinging” of the entire crystal growth chamber, inductive stirring is non-contact and relies on no moving parts. The apparatus is much more compact (a coil and power supply) compared to a mechanical support and motor system. The net velocity can be directed normal to the growth interface, as opposed to longitudinally in the case of “swinging”, which should enhance growth rates. In addition, heating of the growth solution can occur simultaneously through induced currents as opposed to the “swinging” stir method, where a separate heating system must be instituted. All of these advantages will be magnified as the scale of crystal growth (diameter) increases.

With proper design of the power electronics and coil 24 circuitry, simultaneous modulation of the temperature (heat flow from both inductive and conductive effects) and melt 14 velocity (mainly inductive effects) is possible. Specifically, the relative proportions of AC/DC heating can be tuned empirically and on-the-fly to provide gentle mixing while maintaining temperature. Simultaneous optimization of temperature and mixing is possible without the DC field through trial-and-error tuning of the coil 24 and melt 14 properties (coupling efficiencies, heat transfer rates, etc.). This has advantages in crystal 20 growth by facilitating growth in a specific temperature-melt velocity growth regime.

This scheme will extend the lifetimes of reactor vessels, as well as increase process cycle time and efficiency. A further benefit of internal heating is the ability to use stainless steel “off-the-shelf” reactor vessels 10 designed for high pressures (˜10 MPa) at moderate (<600° C.) temperatures, since the reactor's 10 walls can be well-insulated with respect to the hot molten metal. Without internal heating, procurement of “off-the-shelf” pressure vessels capable of 800° C./5 MPa may be difficult, requiring costly custom designs and alloys (Inconel, etc.).

### Nomenclature

The terms “Group-III nitride” or “III-nitride” or “nitride” as used herein refer to any composition or material related to (Al,B,Ga,In)N semiconductors having the formula Al_{w}BₓGa_{y}In_{z}N where 0≦w≦1, 0≦x≦1, 0≦y≦1, 0≦z≦1, and w+x+y+z=1. These terms as used herein are intended to be broadly construed to include respective nitrides of the single species, Al, B, Ga, and In, as well as binary, ternary and quaternary compositions of such Group III metal species. Accordingly, these terms include, but are not limited to, the compounds of AIN, GaN, InN, AlGaN, AlInN, InGaN, and AlGaInN. When two or more of the (Al,B,Ga,In)N component species are present, all possible compositions, including stoichiometric proportions as well as off-stoichiometric proportions (with respect to the relative mole fractions present of each of the (Al,B,Ga,In)N component species that are present in the composition), can be employed within the broad scope of this invention. Further, compositions and materials within the scope of the invention may further include quantities of dopants and/or other impurity materials and/or other inclusional materials.

This invention also covers the selection of particular crystal terminations and polarities of Group-III nitrides. Many Group-III nitride devices are grown along a polar orientation, namely a c-plane {0001} of the crystal, although this results in an undesirable quantum-confined Stark effect (QCSE), due to the existence of strong piezoelectric and spontaneous polarizations. One approach to decreasing polarization effects in Group-III nitride devices is to grow the devices along nonpolar or semipolar orientations of the crystal.

The term “nonpolar” includes the {11-20} planes, known collectively as α-planes, and the {10-10} planes, known collectively as m-planes. Such planes contain equal numbers of Group-III and Nitrogen atoms per plane and are charge-neutral. Subsequent nonpolar layers are equivalent to one another, so the bulk crystal will not be polarized along the growth direction.

The term “semipolar” can be used to refer to any plane that cannot be classified as c-plane, a-plane, or m-plane. In crystallographic terms, a semipolar plane would be any plane that has at least two nonzero h, i, or k Miller indices and a nonzero 1 Miller index. Subsequent semipolar layers are equivalent to one another, so the crystal will have reduced polarization along the growth direction.

When identifying orientations using Miller indices, the use of braces, { }, denotes a set of symmetry-equivalent planes, which are represented by the use of parentheses, ( ). The use of brackets, [ ], denotes a direction, while the use of brackets, < >, denotes a set of symmetry-equivalent directions.

### Conclusion

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method for growing a compound crystal, comprising:
growing a Group-III nitride crystal using a flux-based growth, wherein the flux-based growth includes a solution comprised of at least one Group-III metal contained within a reactor vessel, and the solution is mixed through inductive stirring using one or more electromagnetic fields.

2. The method of claim 1, wherein:
the solution is a conductive solution,
the reactor vessel includes a helical electromagnetic coil wound around a non-conducting crucible containing the conductive solution, and
an electrical field at a specified frequency is applied to the helical electromagnetic coil to create the electromagenetic fields, in order to create currents within the conductive solution, resulting in a flux of the conductive solution impinging on the Group-III nitride crystal's growth interface.

3. The method of claim 2, wherein the electromagnetic fields are controlled to create a directed flow of the solution towards the Group-III nitride crystal's growth interface.

4. The method of claim 2, wherein the electromagnetic fields are controlled to vary the solution's flow velocity and direction during the Group-III nitride crystal's growth.

5. The method of claim 2, wherein the electromagnetic fields heat the solution.

6. The method of claim 2, wherein the solution includes at least one of the following conductive metals: Ga, Na, Li, K, Sn, Bi, or Ca.

7. The method of claim 2, wherein one or more electrically conductive components exist as a discrete phase within the solution.

8. The method of claim 7, wherein the electrically conductive components include at least one of the following elements: W, Re, Ta, Os, Ir, Pt, Au, Pd, Ni, Cu, Ti, Ru, Fe, C, or Si.

9. A crystal grown by the method of claim 1.

10. A substrate or device created using the crystal of claim 9.

11. An apparatus for growing a compound crystal, comprising:
a reactor vessel for growing a Group-III nitride crystal using a flux-based growth, wherein the flux-based growth method includes a solution comprised of at least one Group-III metal contained within the reactor vessel, and the solution is mixed through inductive stirring using one or more electromagnetic fields.

12. The apparatus of claim 11, wherein:
the solution is a conductive solution,
the reactor vessel includes a helical electromagnetic coil wound around a non-conducting crucible containing the conductive solution, and
an electrical field at a specified frequency is applied to the helical electromagnetic coil to create the electromagenetic fields, in order to create currents within the conductive solution, resulting in a flux of the conductive solution impinging on the Group-III nitride crystal's growth interface.

13. The apparatus of claim 12, wherein the electromagnetic fields are controlled to create a directed flow of the solution towards the Group-III nitride crystal's growth interface.

14. The apparatus of claim 12, wherein the electromagnetic fields are controlled to vary the solution's flow velocity and direction during the Group-III nitride crystal's growth.

15. The apparatus of claim 12, wherein the electromagnetic fields heat the solution.

16. The apparatus of claim 12, wherein the solution includes at least one of the following conductive metals: Ga, Na, Li, K, Sn, Bi, or Ca.

17. The apparatus of claim 12, wherein one or more electrically conductive components exist as a discrete phase within the solution.

18. The apparatus of claim 17, wherein the electrically conductive components include at least one of the following elements: W, Re, Ta, Os, Ir, Pt, Au, Pd, Ni, Cu, Ti, Ru, Fe, C, or Si.
